(19) United States
(12) Patent Application Publication
(10) Pub. No.: US 2025/0079303 A1
(43) Pub. Date: Mar. 6, 2025

(54) INTEGRATED CIRCUIT DEVICES WITH BACKSIDE BIT LINES AND WORD LINES

(71) Applicant: Intel Corporation, Santa Clara, CA (US)

(72) Inventors: Shairfe Salahuddin, Portland, OR (US); Mudit Bhargava, Austin, TX (US); Sakthi Prashanth, Portland, OR (US)

(73) Assignee: Intel Corporation, Santa Clara, CA (US)

(21) Appl. No.: 18/459,664

(22) Filed: Sep. 1, 2023

(51) Int. Cl. H01L 23/528; H01L 23/522; H10B 10/00; H10B 12/00

(52) U.S. Cl. CPC H01L 23/528; H01L 23/5226; H10B 10/12; H10B 12/482; H10B 12/488

(57) ABSTRACT

A memory device may include one or more semiconductor structures having a frontside and a backside, one or more gate electrodes, and metal layers at both the frontside and backside. A frontside metal layer may include metal lines that are used as bit lines of the memory device. A backside metal layer may include metal lines that are used as write bit lines of the memory device. A write bit line at the backside may be parallel to a bit line at the frontside. Another backside metal layer may include metal lines that are used as word lines of the memory device. A word line at the backside may be parallel to a gate electrode. A switch may be between a bit line and a write bit line. The bit line is electrically coupled to the write bit line when the switch is closed.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device with metal layers at both frontside and backside, according to some embodiments of the disclosure.

FIG. 2 is a top view of an IC device with backside bit lines and word lines, according to some embodiments of the disclosure.

FIGS. 3A and 3B are perspective views of memory devices with backside bit lines and word lines, according to some embodiments of the disclosure.

FIG. 4 illustrates word line landing in a memory cell, according to some embodiments of the disclosure.

FIG. 5 is an electric circuit diagram of an example SRAM cell, according to some embodiments of the present disclosure.

FIGS. 6A and 6B are top views of a wafer and dies, according to some embodiments of the disclosure.

FIG. 7 is a side, cross-sectional view of an example IC package that may include one or more IC devices with backside bit lines and word lines, according to some embodiments of the disclosure.

FIG. 8 is a cross-sectional side view of an IC device assembly that may include components having one or more IC devices with backside bit lines and word lines, according to some embodiments of the disclosure.

FIG. 9 is a block diagram of an example computing device that may include one or more components with backside bit lines and word lines, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to static random-access memory (SRAM). Other embodiments of the present disclosure may refer to dynamic random-access memory (DRAM). However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A memory cell usually includes a memory element, which stores information, and an access transistor, which is coupled to the memory element and controls access to the memory element. A memory device also includes bit lines and word lines coupled to memory cells. A bit line can couple the memory cells in the memory array to the memory control circuitry. A bit line can be used for reading and writing data. A word line can be used to control the access to a specific row of memory cells in the memory array. When the word line is activated, it enables the data stored in the selected row to be read or modified.

One challenge common to memory arrays is undesirably high resistance of bit lines and word lines. Currently available memory devices usually have bit lines and word lines implemented in frontside metal layers. Frontside metal layers can have high resistance due to their limited thickness. The high resistance can impair performance of memory devices. For instance, write margin of memory devices can be degraded. Also, higher resistance of bit lines and word lines with higher resistance can make transistors slower. Furthermore, multiple metal layers are usually used for word line and bit line routing. The routing can occupy up to several metal layers, which results in complicated metal layers patterning and high cost.

Embodiments of the present disclosure may improve on at least some of the challenges and issues described above by providing memory devices with backside word lines and bit lines. Compared with frontside bitlines and word lines, backside word lines and bitlines can have lower resistance and therefore, improving the performance and write margin of memory devices. Moreover, by implementing bit lines and word lines at the backside, jogs and notches can be avoided in the frontside metal layers, which can reduce cost and complication in metal layer patterning.

In various embodiments of the present disclosure, a memory device may include one or more transistors fabricated based on one or more semiconductor structures. For instance, the source, drain, or channel region of the transistor may be part of a semiconductor structure. The one or more semiconductor structures may have a frontside and a backside. Metal layers may be present at the frontside and the backside. A metal layer may include one or more metal lines that may be in parallel with each other. A frontside metal layer may include metal lines that are used as bit lines of the memory device. A backside metal layer may include metal lines that are used as write bit lines of the memory device. A write bit line at the backside may be coupled to the one or more bit lines at the frontside directly (e.g., using one or more vias) or indirectly (e.g., through one or more intermediate metal layers or transistors). A write bit line at the backside may be parallel to a bit line at the frontside. Another backside metal layer may include metal lines that are used as word lines of the memory device. A word line at the backside may be coupled to the one or more gate electrodes directly (e.g., using one or more vias) or indirectly (e.g., through one or more intermediate metal layers). A word line may be parallel to one or more gate electrode of the one or more transistors. A switch may be between a bit line and a write bit line. The bit line is electrically coupled to the write bit line when the switch is closed.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

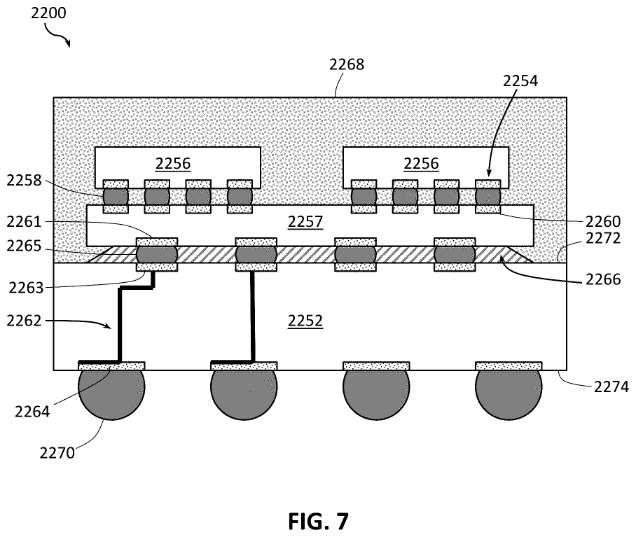

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of backside bit lines and word lines as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various backside bit lines and word lines as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

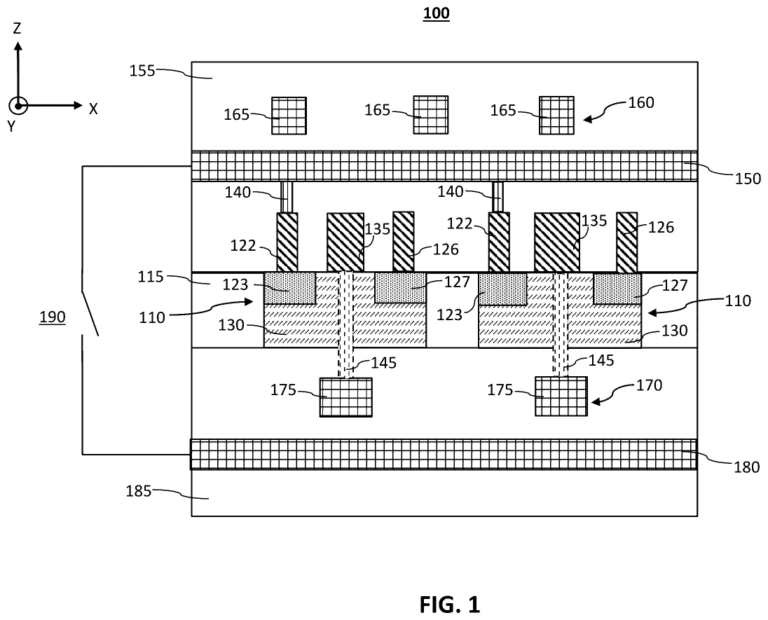

FIG. 1 illustrates an IC device 100 with metal layers at both frontside and backside, according to some embodiments of the disclosure. In addition to the metal layers, the IC device 100 also includes transistors 110 (individually referred to as “transistor 110”), a support structure 115, vias 140 (individually referred to as “via 140”), vias 145 (individually referred to as “via 145”), and electrical insulators 155 and 185, and a switch 190. In other embodiments, the IC device 100 may include fewer, more, or different components. For instance, the IC device 100 may include more transistors, or other semiconductor devices not shown in FIG. 1. Also, the IC device 100 may include a different number of metal layers, vias, electrical insulators, or switches.

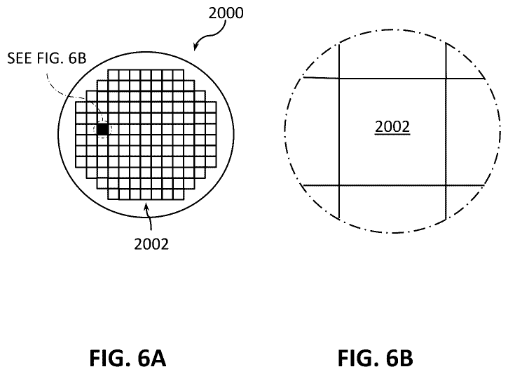

The support structure 115 may be any suitable structure, such as a substrate, a die, a wafer, or a chip, based on which the transistors 110 can be built. The support structure 115 may, e.g., be the wafer 2000 of FIG. 6A, discussed below, and may be, or be included in, a die, e.g., the singulated die 2002 of FIG. 6B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 110, may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

A transistor 110 may be an access transistor in a memory cell. In some embodiments, a transistor 110 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 110 includes a semiconductor structure that includes a channel region 130, a source region 123, and a drain region 127. The transistor 110 includes a semiconductor structure that includes a channel region 130, a source region 123, and a drain region 127. The semiconductor structure of each transistor 110 may be at least partially in the support structure 115. The support structure 115 may include a semiconductor material, from which at least a portion of the semiconductor structure is formed. The semiconductor structure of a transistor 110 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

Each channel region 130 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where the transistor 110 is an NMOS (N-type metal-oxide-semiconductor) transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the transistor 110 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic Ill-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)s. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In each transistor 110, the source region 143 and the drain region 147 are connected to the channel region 130. The source region 143 and the drain region 147 each includes a semiconductor material with dopants. In some embodiments, the source region 143 and the drain region 147 have the same semiconductor material, which may be the same as the channel material of the channel region 130. A semiconductor material of the source region 143 or the drain region 147 may be a Group IV material, a compound of Group IV materials, a Group Ill/V material, a compound of Group Ill/V materials, a Group II/VI material, a compound of Group II/VI materials, or other semiconductor materials. Example Group II materials include zinc (Zn), cadmium (Cd), and so on. Example Group Ill materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group Ill/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 143 and the drain region 147 are the same type. In other embodiments, the dopants of the source region 143 and the drain region 147 may be different (e.g., opposite) types. In an example, the source region 143 has N-type dopants and the drain region 147 has P-type dopants. In another example, the source region 143 has P-type dopants and the drain region 147 has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region 143 and the drain region 147 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 143 and the drain region 147 may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 143 and the drain region 147. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 143 and the drain region 147, for example below 10¹⁵ cm⁻³ or below 10¹³ cm⁻³. Depending on the context, the term “S/D terminal” may refer to a S/D region or a S/D contact or electrode of a transistor.

A transistor 110 also includes a source contact 122 over the source region 123 and a drain contact 126 over the drain region 127. The source contact 122 is also referred to as a source electrode. The drain contact 126 is also referred to as a drain electrode. The source contacts 122 and the drain contacts 146 are electrically conductive and may be coupled to source and drain terminals for receiving electrical signals. A source contact 122 or the drain contact 126 includes one or more electrically conductive materials, such as metals. Examples of metals in the source contacts 122 and the drain contacts 146 may include, but are not limited to, Ruthenium (Ru), copper (Cu), cobalt (Co), palladium (Pd), platinum (Pt), nickel (Ni), and so on.

Each transistor 110 also includes a gate that is over or wraps around at least a portion of the channel region 130. The gate of the transistor 110 includes a gate contact 135. The gate contact 135 may also be referred to as a gate electrode. The gate of the transistor 110B includes a gate contact 135. The gate contact 135 can be coupled to a gate terminal that controls gate voltages applied on the transistor 110. The gate contact 135 may include one or more gate electrode materials, where the choice of the gate electrode materials may depend on whether the transistor 110 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate contact 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate of a transistor 110 may also include a gate insulator (not show in FIG. 1) that separates at least a portion of the channel region 130 from the gate electrode so that the channel region 130 is insulated from the gate electrode. In some embodiments, the gate insulator may wrap around at least a portion of the channel region 130. The gate insulator may also wrap around at least a portion of the source region 143 or the drain region 147. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The metal layers in the IC device 100 include metal layers 150 and 160 at the frontside and metal layers 170 and 180 at the backside. In the embodiments of FIG. 1, the metal layer 150 is the first metal layer at the frontside. The metal layer 160 is the second metal layer at the frontside and is further from the transistor 110 than the metal layer 150. The metal layer 170 is the first metal layer at the backside. The metal layer 180 is the second metal layer at the backside and is further from the transistors 110 than the metal layer 170. In other embodiments, the IC device 100 may have additional metal layers. Also, the position of the metal layer 150, 160, 170, or 180 may be different from the position shown in FIG. 1. The metal layer 150 may be referred to as M0, and the metal layer 160 may be referred to as M1.

Even though FIG. 1 shows a single metal line in the metal layer 150, the metal layer 150 may include one or more other metal lines. A metal line in the metal layer 150 may have a longitudinal axis along the X axis. The metal layer 160 includes metal lines 165, individually referred to as metal line 165. The metal layer 170 includes metal lines 175, individually referred to as metal line 175. A metal line 175 may have a longitudinal axis along the Y axis. In some embodiments, a metal line 175 may be parallel to a gate contact 135. Even though FIG. 1 shows a single metal line in the metal layer 180, the metal layer 180 may include one or more other metal lines. A metal line in the metal layer 180 may have a longitudinal axis along the X axis. In some embodiments, a metal line in the metal layer 180 may be parallel to a metal line in the metal layer 150.

A metal line may be an electrically conductive structure. A metal line may also be referred to as a conductive line, a metal track, a conductive track, or an interconnect. In some embodiments, a metal line may include one or more metals, such as tungsten (W), molybdenum (Mo), ruthenium (Ru), copper (Cu), other metals, or some combination thereof. Metal lines are shown as rectangles in FIG. 1 for the purpose of simplicity and illustration. A metal line may have different shapes in other embodiments. A metal line may have a transvers cross-section perpendicular to its longitudinal axis. In some embodiments, metal lines at the same side may have the same or similar thickness, i.e., the dimension along the Z axis. For instance, metal lines in the metal layers 150 and 160 may have the same or similar thickness, and metal lines in the metal layers 170 and 180 may have the same or similar thickness. A metal line at the backside may have a smaller thickness than a metal line at the frontside, so the backside metal line can have lower resistance than the frontside metal line.

The metal layers 150, 160, 170, and 180 may be electrically coupled to the transistors 110. For instance, the metal layer 150 is coupled to the source contacts 122 of the the transistors 110 through the vias 140. Each via 140 has an end connected to the metal layer 150 and another end connected to a source contact 122. Also, the metal layer 170 is coupled to the gate contacts 135 of the transistors 110 through the vias 145. Each via 145 has an end connected to a metal line 175 and another end connected to a gate contact 135. In some embodiments, the metal layer 150 may function as bit lines of a memory array, and the metal layer 170 may function as word lines of the memory array. The memory array may also include the metal layer 180, which may function as write bit lines. As shown in FIG. 1, the metal layer 180 can be coupled to the metal layer 150 when the switch 190 is closed. The switch 190 may close for a data write operation for writing data into the memory array. The switch 190 may open for a data read operation for reading data from the memory array. Data may be stored using the transistors 110.

The metal layer 160 may facilitate operations of the transistors 110 by providing power or electrical signals to the transistors 110, such as to the source contacts 122, the drain contacts 146, or the gate contacts 135. In an example, a metal line 165 in the metal layer 160 may be coupled to a source contact 142, e.g., through one or more vias. A via (e.g., a via coupling the metal layer 160 to a transistor 110, a via 140, or a via 145 is electrically conductive. A via may include a metal, such as tungsten (W), molybdenum (Mo), ruthenium (Ru), copper (Cu), or other metals.

In some embodiments, the IC device 100 may include an additional metal layer (not shown in FIG. 1) above the metal layer 160. The additional metal layer may include metal lines coupled to the drain contacts 126. A metal line additional metal layer may have a longitudinal axis that is parallel to the longitudinal axis of a metal line in the metal layer 150, e.g., along the X axis. The additional metal layer may be denser than the metal layer 150. For instance, a dimension of a metal line in the additional metal layer along the Y axis may be larger than a dimension of a metal line in the metal layer 150 along the Y axis. The denser metal layer may have a lower resistance. In some embodiments, the total number of frontside metal layers in the IC device 100 may be no more than five, or even no more than three, as backside metal layers (e.g., the metal layers 170 and 180) can be used as bit lines and word lines.

The electrical insulators 155 and 185 may separate conductive structures and semiconductor structures in the IC device 100 from each other so that they are shorted to each other. The electrical insulator 155 or 185 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 155 or 185 may include a first electrical insulator and a second electrical insulator with the second electrical insulator at least partially surrounding the first electrical insulator.

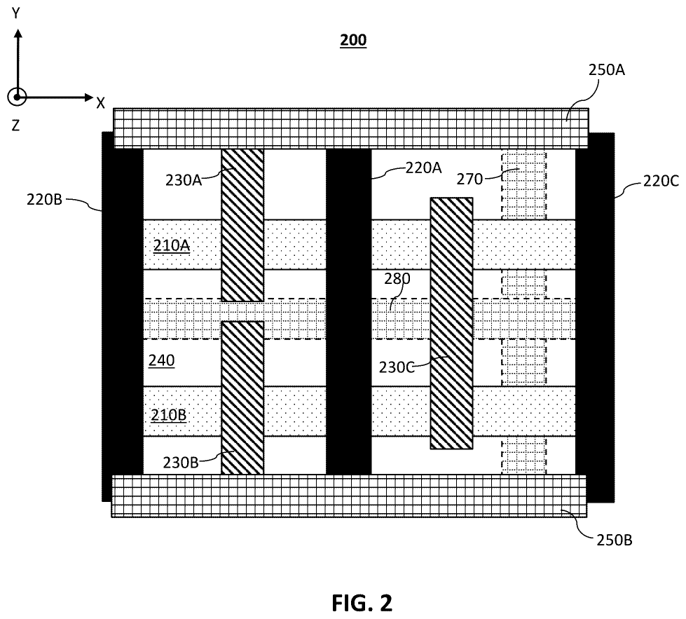

FIG. 2 is a top view of an IC device 200 with backside bit lines and word lines, according to some embodiments of the disclosure. The IC device 200 may be an embodiment of at least part of the IC device 100 in FIG. 1. As shown in FIG. 2, the IC device 200 includes semiconductor structures 210A and 210B (collectively referred to as “semiconductor structures 210” or “semiconductor structure 210”), gate electrodes 220A-220C (collectively referred to as “gate electrodes 220” or “gate electrode 220”), electrodes 230A-230C (collectively referred to as “electrodes 230” or “electrode 230”), metal lines 250A and 250B (collectively referred to as “metal lines 250” or “metal line 250”), a metal line 270, a metal line 280, and an electrical insulator 240. In other embodiments, the IC device 100 may include different, fewer, or more components. For example, the IC device 100 may include a different number of semiconductor structures, metal lines, gate electrodes, source electrodes, or drain electrodes.

In some embodiments, the IC device 200 may be at least part of a memory cell, such as a SRAM bit cell. FIG. 2 shows an X axis, a Y axis, and a Z axis. The X axis may be the vertical axis of the memory cell. The dimension of the memory cell along the X axis (e.g., the distance between the two opposing boundaries of the memory cell along the Y axis) may be the height of the memory cell. The dimension of the memory cell along the Y axis (e.g., the distance between the two opposing boundaries of the memory cell along the X axis) may be the width of the memory cell. The distance between two adjacent gate electrodes 220 (e.g., the distance between the gate electrodes 220A and 220B or the distance between the gate electrodes 220A and 220C) may be the contacted poly pitch of the memory cell. In some embodiments, metal layers (e.g., metal layers including the metal lines 250, 270, and 280) may be arranged over the memory cell in a direction along the Z axis.

A semiconductor structure 210 may include one or more semiconductor materials. In some embodiments, a semiconductor structure 210 may be a semiconductor substrate based on which transistors can be formed. In some embodiments, the semiconductor structures 210 may include semiconductors with opposite doping types. For instance, the semiconductor structure 210A may be a N-type semiconductor structure, while the semiconductor structure 210B may be a P-type semiconductor structure. In other embodiments, the semiconductor structures 210 may include semiconductors with the same doping type. In some embodiments, a semiconductor structure 210 may have a planar structure. In other embodiments, a semiconductor structure 210 may have a non-planar structure, such as fin, nanoribbon, and so on.

A semiconductor structure 210 may have a longitudinal axis. In some embodiments, a dimension of the semiconductor structure 210 along its longitudinal axis may be greater than the dimension of the semiconductor structure 210 in a direction perpendicular to the longitudinal axis. For instance, the semiconductor structure 210 may have a longitudinal axis parallel to the Y axis. The dimension of the semiconductor structure 210 along the Y axis may be greater than the dimension of the semiconductor structure 210 along the X axis or the Z axis. The semiconductor structure 210 may also have a transverse cross-section, which may be a cross-section in a plane perpendicular to the its longitudinal axis.

A semiconductor structure 210 may include a source region, channel region, and drain region of a transistor. The channel region may be between the source region and drain region in a direction along the Y axis. The channel region may be over a portion of the gate electrode 220A. The source region may be over a portion of an electrode 230. The drain region may be over a portion of another electrode 230. For instance, a portion of the semiconductor structure 210A under the electrode 230A may be one of the source region and drain region of a transistor, a portion of the semiconductor structure 210A under the gate electrode 220A may be the channel region of the transistor, and a portion of the semiconductor structure 210A under the electrode 230C may be the other one of the source region and drain region of the transistor. Similarly, a portion of the semiconductor structure 210B under the electrode 230B may be one of the source region and drain region of a transistor, a portion of the semiconductor structure 210B under the gate electrode 220A may be the channel region of the transistor, and a portion of the semiconductor structure 210B under the electrode 230C may be the other one of the source region and drain region of the transistor. The two transistors may be FETs. In an embodiment, the two transistors are both P-type transistors, e.g., P-type metal-oxide-semiconductor (PMOS) transistors. In another embodiment, the two transistors are both N-type transistors, e.g., N-type MOS (NMOS) transistors. In yet another embodiment, one of the two transistors is an N-type transistors, while the other one is a P-type transistors.

A gate electrode 220 includes one or more conductive materials, such as metal, polycrystalline silicon, other types of conductive materials, or some combination thereof. In some embodiments, the choice of the conductive materials in the gate electrode 220 (e.g., the gate electrode 220A) may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, a gate electrode 220 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrode 220B or 220C may be a dummy gate electrode. The gate electrode 220B or 220C may not be coupled to any power plane, ground plane, or signal plane.

An electrode 230 may include one or more electrically conductive materials. An electrically conductive material may be metal. Examples of metals in an electrode 230 may include, but are not limited to, Ru, Cu, Co, palladium, platinum, nickel, and so on. In the embodiments of FIG. 2, the electrode 230A is separated from the electrode 230B by the electrical insulator 290. The electrode 230A and the electrode 230B may be at different electrical potentials during the operation of the IC device 100. The electrode 230C may constitute the electrodes of two transistors, the source or drain region of which may be subject to the same electrical potential. In other embodiments, the memory cell may include a single electrode in lieu of the electrodes 230A and 230B. Also, the memory cell may include two separate electrodes in lieu of the electrode 230C. Even though not shown in FIG. 2, a gate electrode 220 or an electrode 230 may be separated from the electrical insulator 290 by a dielectric material. In some embodiments, the gate electrode 220 or electrode 230 may be partially or wholly wrapped by the dielectric material.

The metal lines 250 may be in a metal layer that is above the semiconductor structures 210, gate electrodes 220, and electrodes 230 along the Z axis. In some embodiments, the metal lines 250 have longitudinal axes that are parallel (including parallel and near parallel) to each other. In some embodiments, the metal lines 250 may be separated from each other by one or more electrical insulators. In some embodiments, a metal line 250 may be a bit line in a memory array. The metal line 250 may be electrically coupled to one or more of the electrodes 230, e.g., through one or more vias (not shown in FIG. 2). In other embodiments, a metal line 250 may be a power plane and a ground plane, respectively, which can deliver power to transistors or other devices in the IC device 200. The IC device 100 may include one or more other metal layers stacked over (above or below) the metal layer in a direction along the Z axis.

The metal line 270 may be in a metal layer that is below the semiconductor structures 210, gate electrodes 220, and electrodes 230 along the Z axis. In some embodiments, the metal line 270 may have a longitudinal axis that is parallel to the gate electrodes 220 and electrodes 230. There may be no other metal layers between the gate electrodes 220 and the metal line 270 along the Z axis. In some embodiments, the metal line 270 may be a word line in a memory array. The metal line 270 may be electrically coupled to one or more of the gate electrodes 220, e.g., through one or more vias or a switch. The IC device 200 may include one or more other metal lines that are in the same metal layer as the metal line 270. The one or more other metal lines may each have a longitudinal axis that is parallel to the gate electrodes 220 and electrodes 230.

The metal line 280 may be in another metal layer that is below the semiconductor structures 210, gate electrodes 220, and electrodes 230 along the Z axis. In some embodiments, the metal line 280 may be a bit line (e.g., a word bit line) in a memory array. The metal line 280 may be electrically coupled to one or more of the electrodes 230, e.g., through one or more vias or a switch. In some embodiments, the metal line 280 may be electrically coupled to one or both metal lines 250. The IC device 200 may include one or more other metal lines that are in the same metal layer as the metal line 280. The one or more other metal lines may each have a longitudinal axis that is parallel to the metal lines 250. In some embodiments, the metal line 280 may have a longitudinal axis that is parallel to the metal lines 250. In some embodiments, the metal layer including the metal line 280 may be below the metal layer including the metal line 270. In other embodiments, the metal layer including the metal line 280 may be between the metal layer including the metal line 270 and the semiconductor structures 210 along the Z axis.

The electrical insulator 290 may separate and insulate semiconductor components or conductive components in the IC device 200. In some embodiments, the electrical insulator 290 may wholly or partially wrap one or more other components of the IC device 200. For instance, the electrical insulator 290 may wholly or partially wrap a semiconductor structure 210, gate electrode 220, electrode 230, metal line 250, metal line 270, metal line 280, and so on. The electrical insulator 290 may include one or more electrical insulative materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

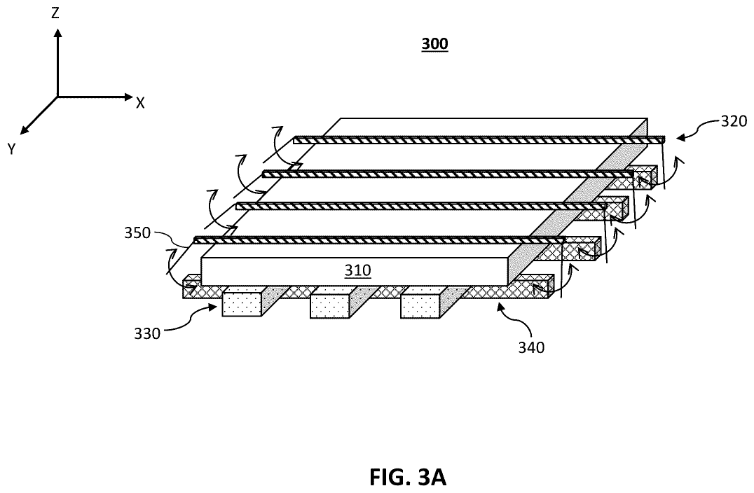

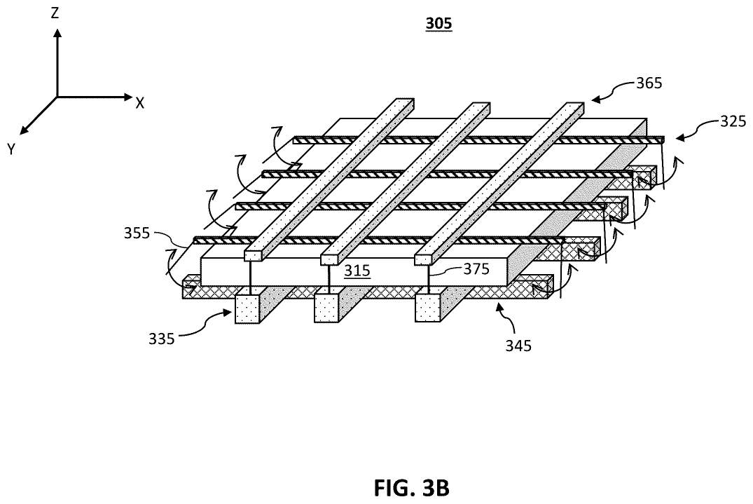

FIGS. 3A and 3B are perspective views of memory devices with backside bit lines and word lines, according to some embodiments of the disclosure. FIG. 3A illustrates a memory device 300 including a body 310, three metal layers 320, 330, and 340, and a plurality of switches 350 (individually referred to as switch 350). The body 310 may include one or more semiconductor structures, one or more electrodes, other types of components, or some combination thereof. For the purpose of simplicity and illustration, the components in the body 310 are not shown in FIG. 3A. As shown in FIG. 3A, the body 310 has a plane that is parallel to the X-Y plane.

The metal layer 320 is above the body 310, and the metal layers 330 and 340 are below the body 310. The metal layer 320 may be an embodiment of the metal layer 150 in FIG. 1. The metal layer 330 may be an embodiment of the metal layer 170 in FIG. 1. The metal layer 340 may be an embodiment of the metal layer 180 in FIG. 1. Each of the metal layers 320, 330, and 340 includes a plurality of metal lines in parallel. In some embodiments, the metal layer 320 has a smaller dimension along the Z axis than the metal layer 330 or 340.

The metal layer 320 is coupled to the metal layer 340 through the switches 350. In the embodiments of FIG. 3, each metal line in the metal layer 320 is coupled to a metal line in the metal layer 340 through two switches 350 that are at opposite sides of the body 310: one at the left side and one at the right side. In some embodiments, the two switches may be synchronized. For instance, they can open or close at the same time. The state (open/off state or closed/on state) of the two switches may be controlled by control signals, e.g., a control signal from a logic unit associated with the memory array.

The metal layer 320 may be used as bit lines, and the metal layer 340 may be used as write bit lines. In some embodiments, the two switches coupling a bit line to a write bit line may be closed for a data write operation, e.g., for storing data into one or more memory elements of the memory array. The two switches may be open for a data read operation, e.g., for reading data from one or more memory elements of the memory array. The switches 350 may also be referred to as write enable switches. By enabling backside write bitlines in the metal layer 340 with frontside bitlines in the metal layer 320, the IR drop on bit lines can be lower during write operations. An IR drop may be the difference in electrical potential between the two endpoints of an electrical circuit during current flow. The lower IR drop can cause better write margin.

By setting the switches 350 to the off state during a read operation, the capacitance of the memory array can be lower, which can enable faster read. Also, less power would be consumed for the read operation. Additionally, longer word lines or bit lines can lead to higher array efficiency in iso-performance. The macro area can be reduced, meaning the cost for the memory array can be reduced. The switches 350 may add area overhead but the area overhead is minimal. In some embodiments, the area overhead is no more than 1%. The switches 350 may be arranged at edges of the area of the memory array.

FIG. 3B illustrates another memory device 305. Similar to the memory device 300, the memory device 305 includes a body 315, three metal layers 325, 335, and 345, switches 355 (individually referred to as switch 350). Additionally, the memory device 305 includes another metal layer 365. The metal layer 365 is above the metal layer 325 along the Z axis. In an example, the metal layer 325 may be the first frontside metal layer, and the metal layer including the metal layer 365 may be the second frontside metal layer. The metal layer 365 includes metal lines with longitudinal axes along the Y axis. The longitudinal axes may be parallel to the longitudinal axes of the metal lines in the metal layer 335. The metal lines in the metal layer 365 are coupled to the metal lines in the metal layer 335 through connections 375 (individually referred to as connection 375). A connection 375 is electrically conductive and provides a conductive channel between the metal layer 335 and the metal layer 365. In some embodiments, a connection 375 may be a via.

Even though not shown in FIG. 3B, the body 315 may include transistors and capacitors, e.g., in areas between the metal lines. A capacitor may be used to store data. A transistor may be an access transistor that controls access to one or more capacitors. In some embodiments, one or more transistors and one or more capacitors may constitute a memory cell. The body 315 may enclose a plurality of memory cells.

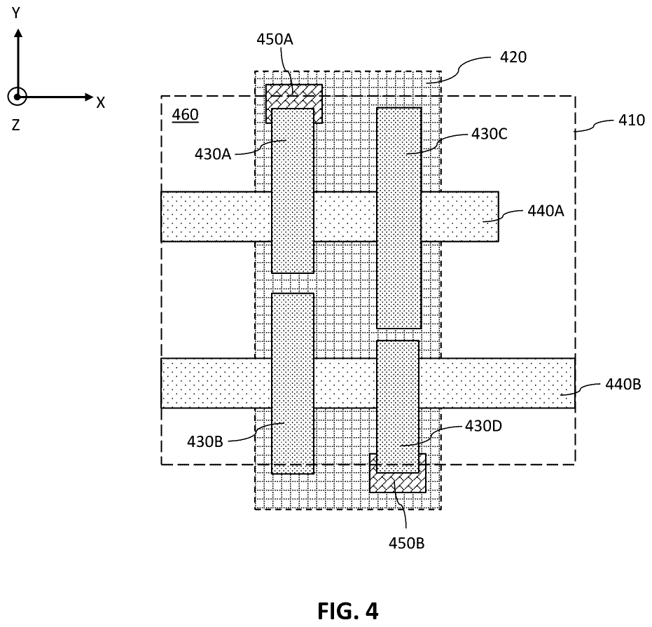

FIG. 4 illustrates word line landing in a memory cell 410, according to some embodiments of the disclosure. For the purpose of simplicity and illustration, FIG. 4 does not show all components of the memory cell 410. The memory cell 410 has boundaries that are represented by dashed lines in FIG. 4. The memory cell 410 includes semiconductor structures 440A and 440B and gate electrodes 430A-430D. A metal layer 420 is over the semiconductor structures 440A and 440B and gate electrodes 430A-430D. Each of the semiconductor structures 440A and 440B may be an embodiment of a semiconductor structure 210 in FIG. 2. Each of the gate electrodes 430A-430D may be an embodiment of a gate electrode 220 in FIG. 2. The metal layer 420 may be an embodiment of a metal layer including the metal line 270 in FIG. 2. The memory cell 410 also includes an electrical insulator 460 that can separate and insulate other components in the memory cell 410.

In the embodiment of FIG. 4, the gate electrode 430A is directly coupled to the metal layer 420 through a via 450A. The via 450A may have an end connected to the gate electrode 430A and another end connected to the metal layer 420. The two ends may oppose each other. The gate electrode 430D is directly coupled to the metal layer 420 through a via 450B. The via 450B may have an end connected to the gate electrode 430D and another end connected to the metal layer 420. The two ends may oppose each other. An embodiment of the via 450A or 450B may be a via 145 in FIG. 1. Even though not shown in FIG. 4, the gate electrode 430B or 430C may also directly coupled to the metal layer 420 through a via.

In other embodiments, one or more of the gate electrodes 430A-430D may be indirectly coupled to the metal layer 420. In an example, the metal layer 420 may be in the backside of the memory cell 410. One or more of the gate electrodes 430A-430D may be directly coupled to a metal layer at the frontside of the memory cell 410, e.g., through one or more vias. The frontside metal layer may be coupled to the metal layer 420. That way, the one or more of the gate electrodes 430A-430D are coupled to the metal layer 420 through the frontside metal layer. In some embodiments, the metal layer 420 functions as word lines of a memory array. The frontside metal layer may also function as word lines of the memory array.

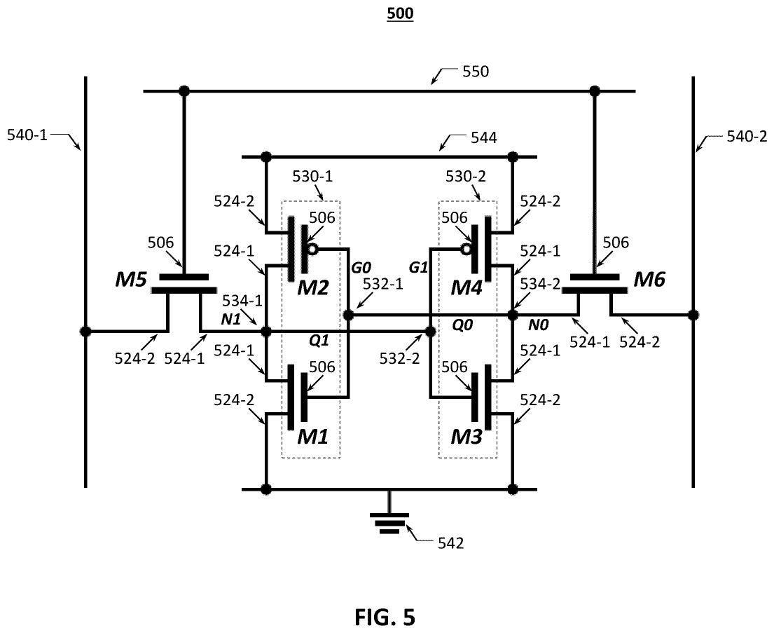

FIG. 5 provides an electric circuit diagram of an example SRAM cell 500, according to some embodiments of the present disclosure. For the purpose of illustration, the SRAM cell 500 is a 6 T memory cell. In other embodiments, the SRAM cell 500 may include a different number of transistors. An embodiment of the SRAM cell 500 may include or be at least part of the IC device 100 in FIG. 1, the IC device 200 in FIG. 2, the memory device 300 in FIG. 3A, the memory device 305 in FIG. 3B, or the memory cell 400 in FIG. 4.

As shown in FIG. 5, the SRAM cell 500 may include transistors M1-M4 for storing a bit value or a memory state (e.g., logic “1” or “0”) of the cell, and two access transistors, M5 and M6, for controlling access to the cell (e.g., access to write information to the cell or access to read information from the cell 500). Each of the transistors M1-M6 may be implemented as an angled transistor as described herein. For example, each of the transistors M1, M3, M5 and M6 is an NMOS transistor and, therefore, may be implemented as the transistor 510 shown in FIG. 5A. Similarly, each of the transistors M2 and M4 is a PMOS transistor and, therefore, may be implemented as the transistor 510 shown in FIG. 5B. To illustrate that the transistors M1-M6 may be implemented as respective transistors 510 of FIGS. 5A-3B, the reference numerals for various elements of the transistors 510 shown in FIGS. 5A-3B are used in FIG. 5 to label analogous elements of the transistors M1-M6. Thus, FIG. 5 illustrates the gates 506 and the first and second S/D contacts 524-1 and 524-2 for each of the transistors M1-M6. An example of a transistor in the SRAM cell 500 may be a transistor 110 in FIG. 1.

In the SRAM cell 500, each bit may be stored on four transistors (M1, M2, M3, M4) that form two cross-coupled inverters 530, each having an input 532 and an output 534. The first inverter 530-1 may be formed by an NMOS transistor M1 and a PMOS transistor M2, while the second inverter 530-2 may be formed by an NMOS transistor M3 and a PMOS transistor M4. As shown in FIG. 5, the gate 506 of the transistor M1 may be coupled to (e.g., directly connected to) the gate 506 of the transistor M2 (where the point of such coupling may be referred to as a node G0, labeled in FIG. 5), and both of these gates 506 may be coupled to the input 532-1 of the first inverter 530-1. Furthermore, the first S/D contact 524-1 of the transistor M1 may be coupled to the first S/D contact 524-1 of the transistor M2 (where the point of such coupling may be referred to as a node N1, labeled in FIG. 5), and both first S/D contacts 524-1 may be coupled to the output 534-1 of the first inverter 530-1. Similarly, for the second inverter 530-2, the gate 506 of the transistor M3 may be coupled to the gate 506 of the transistor M4 (where the point of such coupling may be referred to as a node G1, labeled in FIG. 5), and both of these gate stacks may be coupled to the input 532-2 of the second inverter 530-2, while the first S/D contact 524-1 of the transistor M3 may be coupled to the first S/D contact 524-1 of the transistor M4 (where the point of such coupling may be referred to as a node NO, labeled in FIG. 5), and both of these first S/D contacts 524-1 may be coupled to the output 534-2 of the second inverter 530-2. As also shown in FIG. 5, when the transistors M1 and M3 are NMOS transistors and when the transistors M2 and M4 are PMOS transistors as illustrated in FIG. 5, the second S/D contacts 524-2 of the transistors M1 and M3 may be coupled to a ground voltage 542, while the second S/D contacts 524-2 of the transistors M2 and M4 may be coupled to a supply voltage 544, e.g., VDD. In the embodiments of the SRAM cell 500 where the NMOS transistors shown in FIG. 5 are replaced with PMOS transistors and where the PMOS transistors shown in FIG. 5 are replaced with NMOS transistors, the designation of the ground voltage 542 and the supply voltage 544 would be reversed, all of which embodiments being within the scope of the present disclosure.

The four transistors M1-M4 in such configuration form a stable storage cell for storing a bit value of 0 or 1. As further shown in FIG. 5, two additional access transistors, M5 and M6, may serve to control the access to the storage cell of the transistors M1-M4 during read and write operations. As shown in FIG. 5, the first S/D contact 524-1 of the access transistor M5 may be coupled to the output 534-1 of the first inverter 530-1. Phrased differently, the first S/D contact 524-1 of the access transistor M5 may be coupled to (e.g., directly connected to) each of the first S/D contact 524-1 of the transistor M1 and the first S/D contact 524-1 of the transistor M2, where the node N1 shown in FIG. 5 is the point of such coupling. The second S/D contact 524-2 of the access transistor M5 may be coupled to a first BL 540-1. Thus, each of the first S/D contact 524-1 of the transistor M1 and the first S/D contact 524-1 of the transistor M2 may be coupled to the first BL 540-1 (e.g., via the access transistor M5). The gate 506 of the access transistor M5 may be coupled to a WL 550. As further shown in FIG. 5, the first S/D contact 524-1 of the access transistor M6 may be coupled to the output 534-2 of the second inverter 530-2. Phrased differently, the first S/D contact 524-1 of the access transistor M6 may be coupled to (e.g., directly connected to) each of the first S/D contact 524-1 of the transistor M3 and the first S/D contact 524-1 of the transistor M4, where the node NO shown in FIG. 5 is the point of such coupling. The second S/D contact 524-2 of the access transistor M6 may be coupled to a second BL 540-2. Thus, each of the first S/D contact 524-1 of the transistor M3 and the first S/D contact 524-1 of the transistor M4 may be coupled to the second BL 540-2 (e.g., via the access transistor M6). The gate 506 of the access transistor M6 may be coupled to the WL 550. Thus, the gates 506 of both of the access transistors M5 and M6 may be coupled to a single, shared, WL, the WL 550. As also shown in FIG. 5, the input 532-1 of the first inverter 530-1 (e.g., the node G0) may be coupled to (e.g., directly connected to) the first S/D contact 524-1 of the access transistor M6 (e.g., the node NO), via an interconnect Q0, labeled in FIG. 5. Similarly, FIG. 5 illustrates that the input 532-2 of the second inverter 530-2 (e.g., the node G1) may be coupled to (e.g., directly connected to) the first S/D contact 524-1 of the access transistor M5 (e.g., the node N1), via an interconnect Q1, labeled in FIG. 5. In other words, each of the gate 506 of the transistor M1 and the gate 506 of the transistor M2 may be coupled to the first S/D contact 524-1 of the access transistor M6, while each of the gate 506 of the transistor M3 and the gate 506 of the transistor M4 may be coupled to the first S/D contact 524-1 of the access transistor M5. Phrased differently, each of the gate 506 of the transistor M1 and the gate 506 of the transistor M2 may be coupled to the second BL 540-2 (e.g., via the access transistor M6), while each of the gate 506 of the transistor M3 and the gate 506 of the transistor M4 may be coupled to the first BL 540-1 (e.g., via the access transistor M5).

The WL 550 and the first and second BLs 540 may be used together to read and program (e.g., write to) the SRAM cell 500. In particular, access to the cell may be enabled by the WL 550 which controls whether the two access transistors M5 and M6 are on or off. In turn, the access transistors M5 and M6 control whether the SRAM cell 500 is connected to the BLs 540-1 and 540-2. During operation of the SRAM cell 500, a signal on the first BL 540-1 may be complementary to a signal on the second BL 540-2 (e.g., then the signal on the first BL 540-1 is HIGH or logic “1” the signal on the second BL 540-2 may be LOW or “logic 0,” and vice versa). The two BLs 540 may be used to transfer data for both read and write operations of the SRAM cell 500. In other embodiments of the SRAM cell 500, only a single BL 540 may be used, instead of two bitlines 540-1 and 540-2, although having one signal BL and one inverse or complementary BL, such as the two BLs 540 shown in FIG. 5, may help improve noise margins.

During read accesses, the BLs 540 may be actively driven HIGH and LOW by the inverters 530 in the SRAM cell 500. This may improve SRAM bandwidth compared to dynamic random-access memory (DRAM). The symmetric structure of the SRAMs cell 500 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, e.g., higher bits followed by lower bits, over the same package pins to keep their size and cost down.

Each of the WL 550 and the BLs 540, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIGS. 6A and 6B are top views of a wafer 2000 and dies 2002, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. An IC device may include backside bit lines and word lines. Examples of the IC device may include the IC device 100 in FIG. 1, the IC device 200 in FIG. 2, the memory device 300 in FIG. 3, the memory device 305 in FIG. 3, and so on. Each of the dies 2002 may be a repeating unit of a semiconductor product that includes any suitable IC (e.g., ICs with backside bit lines and word lines as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include backside bit lines and word lines as disclosed herein may take or include components that take the form of the wafer 2000 (e.g., not singulated) or the form of the die 2002 (e.g., singulated). The die 2002 may include one or more diodes, one or more transistors (e.g., one or more Ill-N transistors as described herein) as well as, optionally, supporting circuitry to route electrical signals to the Ill-N diodes with n-doped wells and capping layers and Ill-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with backside bit lines and word lines, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

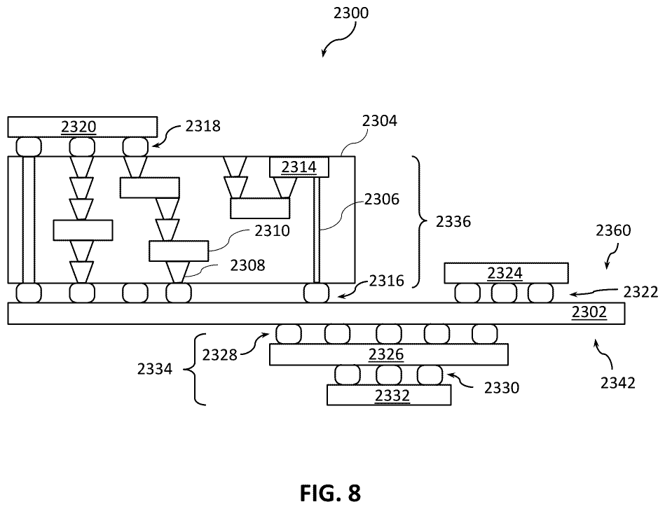

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may include any of the embodiments of an IC device with backside bit lines and word lines. In embodiments in which the IC package 2200 includes multiple dies 2256, the IC package 2200 may be referred to as a multi-chip package. Importantly, even in such embodiments of an MCP implementation of the IC package 2200, one or more IC devices with backside bit lines and word lines may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, any of the dies 2256 may include one or more backside metal layers, e.g., backside bit lines and word lines as discussed above; in some embodiments, at least some of the dies 2256 may not include any Ill-N diodes with n-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with backside bit lines and word lines, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with backside bit lines and word lines in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include backside bit lines and word lines in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device of FIG. 1), or any other suitable component. In particular, the IC package 2320 may include one or more with backside bit lines and word lines as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group Ill-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices with backside bit lines and word lines as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

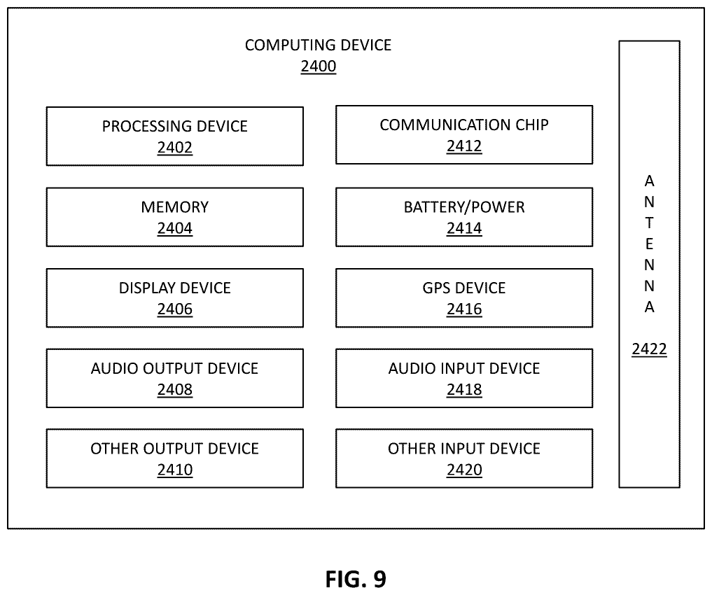

FIG. 9 is a block diagram of an example computing device 2400 that may include one or more components with one or more IC devices with backside bit lines and word lines, according to some embodiments of the disclosure. For example, any suitable ones of the components of the computing device 2400 may include a die (e.g., the die 2002 of FIG. 6B) including backside bit lines and word lines, according to some embodiments of the disclosure. Any of the components of the computing device 2400 may include an IC device (e.g., the IC devices in FIGS. 1A and 1B) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a transistor including a source region, a drain region, a channel region, a first electrode over the channel region, and a second electrode over the source region or the drain region; a first conductive structure at a first side of the channel region, the first conductive structure electrically coupled to the second electrode; a second conductive structure at a second side of the channel region, the second side opposing the first side, the second conductive structure electrically coupled to the first electrode; and a third conductive structure at the second side of the channel region.

Example 2 provides the IC device according to example 1, further including a switch electrically coupled to the first conductive structure and the third conductive structure, where the first conductive structure is electrically coupled to the third conductive structure when the switch is closed.

Example 3 provides the IC device according to example 1 or 2, further including a via including a first end and a second end, the first end of the via connected to the second conductive structure, the second end of the via connected to the first electrode.

Example 4 provides the IC device according to example 3, further including an additional transistor including an additional first electrode; and an additional via including a first end and a second end, the first end of the additional via connected to the second conductive structure, the second end of the additional via connected to the additional first electrode.

Example 5 provides the IC device according to any one of examples 1-4, where a longitudinal axis of the first conductive structure is parallel to a longitudinal axis of the third conductive structure.

Example 6 provides the IC device according to any one of examples 1-5, where a longitudinal axis of the first electrode is parallel to a longitudinal axis of the second conductive structure.

Example 7 provides the IC device according to any one of examples 1-6, where a longitudinal axis of the second conductive structure is perpendicular to a longitudinal axis of the third conductive structure.

Example 8 provides an IC device, including a semiconductor structure; a first layer including a plurality of first bit lines; a second layer including a plurality of second bit lines; and a third layer including a plurality of word lines, where: an individual first bit line is parallel to an individual second bit line, the first layer is at a first side of the semiconductor structure, the second layer and the third layer are at a second side of the semiconductor structure, and the first side opposes the second side.

Example 9 provides the IC device according to example 8, further including an electrically conductive structure over at least a portion of the semiconductor structure, where the electrically conductive structure is between the first layer and the second layer, and an individual word line is parallel to the electrically conductive structure.

Example 10 provides the IC device according to example 8 or 9, where the individual first bit line is for reading data from the memory device, and the individual second bit line is for writing data into the memory device.

Example 11 provides the IC device according to example 10, further including a plurality of switches, an individual switch coupled to the individual first bit line and the individual second bit line, where the first bit line is electrically shorted to the individual second bit line when the individual switch is closed.

Example 12 provides the IC device according to any one of examples 8-11, where the third layer is between the first layer and the second layer.

Example 13 provides the IC device according to any one of examples 8-12, further including a power plane at the first side or the second side of the semiconductor structure.

Example 14 provides the IC device according to any one of examples 8-13, where the memory device is a Static random-access memory.

Example 15 provides an IC device, including a semiconductor structure having a first longitudinal axis; a plurality of conductive structures over portions of the semiconductor structure, an individual conductive structure having a second longitudinal axis that is perpendicular to the first longitudinal axis; a first conductive layer; and a second conductive layer electrically coupled to the individual conductive structure, where the semiconductor structure or the individual conductive structure is between the first conductive layer and the second conductive layer.

Example 16 provides the IC device according to example 15, further including a third conductive layer that is closer to the second conductive layer than to the first conductive layer.

Example 17 provides the IC device according to example 16, further including a plurality of switches between the first conductive layer and the third conductive layer.

Example 18 provides the IC device according to any one of examples 15-17, further including a plurality of vias, an individual via connected to the individual conductive structure and the second conductive layer.

Example 19 provides the IC device according to any one of examples 15-18, where the first conductive layer or the second conductive layer includes a plurality of conductive elements that are in parallel.

Example 20 provides the IC device according to any one of examples 15-19, further including a plurality of additional conductive structures over different portions of the semiconductor structure, an individual additional conductive structure electrically coupled to the first conductive layer.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a transistor comprising a source region, a drain region, a channel region, a first electrode over the channel region, and a second electrode over the source region or the drain region;
a first conductive structure at a first side of the channel region, the first conductive structure electrically coupled to the second electrode;
a second conductive structure at a second side of the channel region, the second side opposing the first side, the second conductive structure electrically coupled to the first electrode; and
a third conductive structure at the second side of the channel region.

2. The IC device according to claim 1, further comprising:
a switch electrically coupled to the first conductive structure and the third conductive structure,
wherein the first conductive structure is electrically coupled to the third conductive structure when the switch is closed.

3. The IC device according to claim 1, further comprising:
a via comprising a first end and a second end, the first end of the via connected to the second conductive structure, the second end of the via connected to the first electrode.

4. The IC device according to claim 3, further comprising:
an additional transistor comprising an additional first electrode; and
an additional via comprising a first end and a second end, the first end of the additional via connected to the second conductive structure, the second end of the additional via connected to the additional first electrode.

5. The IC device according to claim 1, wherein a longitudinal axis of the first conductive structure is parallel to a longitudinal axis of the third conductive structure.

6. The IC device according to claim 1, wherein a longitudinal axis of the first electrode is parallel to a longitudinal axis of the second conductive structure.

7. The IC device according to claim 1, wherein a longitudinal axis of the second conductive structure is perpendicular to a longitudinal axis of the third conductive structure.

8. An integrated circuit (IC) device, comprising:
a semiconductor structure;
a first layer comprising a plurality of first bit lines;
a second layer comprising a plurality of second bit lines; and
a third layer comprising a plurality of word lines,
wherein:
an individual first bit line is parallel to an individual second bit line,
the first layer is at a first side of the semiconductor structure,
the second layer and the third layer are at a second side of the semiconductor structure, and
the first side opposes the second side.

9. The IC device according to claim 8, further comprising:
an electrically conductive structure over at least a portion of the semiconductor structure,
wherein the electrically conductive structure is between the first layer and the second layer, and an individual word line is parallel to the electrically conductive structure.

10. The IC device according to claim 8, wherein the individual first bit line is for reading data from the memory device, and the individual second bit line is for writing data into the memory device.

11. The IC device according to claim 10, further comprising:
a plurality of switches, an individual switch coupled to the individual first bit line and the individual second bit line,
wherein the first bit line is electrically shorted to the individual second bit line when the individual switch is closed.

12. The IC device according to claim 8, wherein the third layer is between the first layer and the second layer.

13. The IC device according to claim 8, further comprising:
a power plane at the first side or the second side of the semiconductor structure.

14. The IC device according to claim 8, wherein the memory device is a Static random-access memory.

15. An integrated circuit (IC) device, comprising:
a semiconductor structure having a first longitudinal axis;
a plurality of conductive structures over portions of the semiconductor structure, an individual conductive structure having a second longitudinal axis that is perpendicular to the first longitudinal axis;
a first conductive layer; and
a second conductive layer electrically coupled to the individual conductive structure,
wherein the semiconductor structure or the individual conductive structure is between the first conductive layer and the second conductive layer.

16. The IC device according to claim 15, further comprising:
a third conductive layer that is closer to the second conductive layer than to the first conductive layer.

17. The IC device according to claim 16, further comprising:
a plurality of switches between the first conductive layer and the third conductive layer.

18. The IC device according to claim 15, further comprising:
a plurality of vias, an individual via connected to the individual conductive structure and the second conductive layer.

19. The IC device according to claim 15, wherein the first conductive layer or the second conductive layer comprises a plurality of conductive elements that are in parallel.

20. The IC device according to claim 15, further comprising:
a plurality of additional conductive structures over different portions of the semiconductor structure, an individual additional conductive structure electrically coupled to the first conductive layer.
